(19) United States
(12) Patent Application Publication
(10) Pub. No.: US 2011/0003087 A1
(43) Pub. Date: Jan. 6, 2011

(54) METHOD AND APPARATUS FOR GENERATING PLASMA

(75) Inventors: Pekka Soininen, Helsinki (FI); Sami Sneck, Vantaa (FI); David Cameron, Majavesi (FI)

Correspondence Address: MERCHANT & GOULD PC, P.O. BOX 2903, MINNEAPOLIS, MN, 55402-0903, US

(73) Assignee: Beneq Oy, Vantaa (FI)

(21) Appl. No.: 12/808,530

(22) PCT Filed: Dec. 16, 2008
(86) PCT No.: PCT/FI2008/050747

§ 371 Date: Sep. 20, 2010

(30) Foreign Application Priority Data
Dec. 17, 2007 (FI) 20075926

(51) Int. Cl. C23C 16/00; H05H 1/24

(52) U.S. Cl. 427/569; 118/723 R

(57) ABSTRACT

A reaction chamber of a reactor for coating or treating a substrate by an atomic layer deposition process (ALD) by exposing the substrate to alternately repeated surface reactions of two or more gas-phase reactants. The reaction chamber is configured to generate capacitively coupled plasma and comprises a reaction space within said reaction chamber, a first inlet to guide gases into the reaction chamber and an outlet to lead gases out of the reaction chamber. The reaction chamber is configured to lead the two or more reactants into the reaction chamber such that the two or more reactants may flow through the reaction space across the substrate in a direction essentially parallel to the inner surface of the lower wall.

### FIELD OF THE INVENTION

The present invention relates to film deposition and processing technology. Especially the present invention relates to a method and an apparatus for plasma assisted deposition and processing.

### BACKGROUND OF THE INVENTION

Atomic Layer Deposition (ALD) is a well known method to deposit uniform thin-films over substrates of various shapes, even over complex 3D structures. The substrates over which the thin-film is to be deposited are placed in a reaction chamber of an ALD reactor for processing. In an ALD process two or more different reactants (also called precursors or precursor materials) are introduced to the reaction chamber in a sequential manner and the reactants adsorb on surfaces e.g. on the substrate with suitable surface energy. In between each reactant pulse there is a purging period during which a flow of inert gas, often called the carrier gas, purges the reaction chamber from e.g. surplus reactants and by-products resulting from the adsorption reactions of the previous reactant pulse. A film is grown by an ALD process by repeating several times a pulsing sequence comprising the afore-mentioned reactant pulses and purging periods. The number of how many times this sequence called the “ALD cycle” is repeated depends on the targeted film thickness.

An ALD process is governed by surface reactions as a result of which a reactant saturates the growth surface which becomes passivated for the same reactant. This results in self-limiting growth of the thin-film as only the following pulse of reactant of a different species is able to adsorb on the substrate. The mechanism of film growth in an ALD process enables very conformal coatings as long as a sufficient dose of reactant is supplied over the substrate during each reactant pulse to achieve surface saturation. Although an ALD process ideally produces one monolayer of conformal film in one pulsing cycle and although the process is less sensitive to flow dynamics than various Chemical Vapour Deposition (CVD) processes there exist many nonidealities which result in nonhomogeneous film growth if reactants are not uniformly distributed over the substrates. Furthermore the flow of reactants through the reaction chamber is preferably such that the reaction byproducts and surplus reactants may be rapidly purged from the reaction chamber after a reactant pulse.

Certain thermodynamical conditions must also be fulfilled in order to avoid decomposition and condensation of reactants in the reaction chamber. In addition to selecting the right precursors for the ALD process a very important aspect is finding the right process temperature. The temperature of the substrate has to be high enough so that the adsorption reactions may happen and e.g. no condensation of the reactants will occur and at the same time the temperature has to be low enough so that the reactants do not e.g. decompose or desorb from the surface of the substrate. A suitable temperature range of the reaction chamber or the surface where film-growth happens through self-limiting surface reactions as described above is often called an “ALD window”, which may vary depending on the process.

For most known thermal ALD processes the “ALD window” is around 200° C.-500° C. This temperature range limits the choice of substrate materials for ALD processes. The substrates must be stable enough to handle the temperatures in the “ALD window”. Furthermore post process treatment of the substrate and/or the film in the same ALD reactor after film-growth is often desirable. This may further increase the stability requirements of the substrate materials.

To reduce the required temperature for ALD growth plasma (plasma assisted) processes have been developed. In these processes energy required for adsorption reactions to take place is supplied into the reaction chamber by means of RF-power which generates plasma (including uncharged radicals) from molecules supplied into the reaction chamber. RF-power can be coupled into a reaction chamber inductively or capacitively. The choice of how RF-power is coupled significantly affects the design of the reaction chamber.

A problem associated with state of the art ALD reaction chamber designs for generating capacitively coupled plasma is that they are not optimized for flow dynamics. U.S. Pat. No. 6,820,570 discloses an ALD reaction chamber design to capacitively generate remote plasma. In this design reactants are supplied from both sides of an electrode placed in the reaction chamber. This electrode further serves the purpose of a flow guide which spreads one of the reactants over the substrate located beneath the flow guide. Different reactants follow different flow paths in the reaction chamber, which causes problems in process control as each reactant spreads differently over the substrates. Therefore flow dynamics should be optimized differently for each reactant with a different flow path, which may be difficult if not impossible. These problems may lead to nonuniformities and nonhomogeneities in the growing film as discussed above. Furthermore purging times for each reactant may be different which may result in difficulties in process optimization where the focus is often on decreasing the time of the ALD cycle. Additionally, a long ALD cycle time may be required if even one of the reactants in an ALD process is supplied into the reaction space such that the reactant flows essentially perpendicularly towards the surface of the substrate, e.g. in a showerhead geometry.

### PURPOSE OF THE INVENTION

The purpose of the present invention is to reduce the aforementioned technical problems of the prior-art by providing a new type of method and apparatus for generating plasma in an atomic layer deposition (ALD) reactor.

### SUMMARY OF THE INVENTION

The apparatus according to the present invention is characterized by what is presented in independent claim 1.

The method according to the present invention is characterized by what is presented in independent claim 13.

The use according to the present invention is characterized by what is presented in independent claim 15.

The apparatus according to the present invention is a reaction chamber of an atomic layer deposition (ALD) reactor for coating or treating a substrate by exposing the substrate to alternately repeated surface reactions of two or more gas-phase reactants, wherein the reactants comprise a first reactant. The reaction chamber is configured to generate capacitively coupled plasma and comprises an upper wall, a lower wall with an essentially planar inner surface for supporting the substrate and at least one side wall extending between the upper wall and the lower wall, to together define a reaction space within said reaction chamber. The reaction chamber further comprises a first inlet to guide gases into the reaction chamber and an outlet to lead gases out of the reaction chamber. In the reaction chamber according to the present invention the first inlet is in flow connection outside the reaction chamber with a source for the first reactant for leading the first reactant into the reaction chamber through the first inlet, and the reaction chamber is configured to lead the two or more reactants into the reaction chamber such that the two or more reactants may flow through the reaction space across the substrate in a direction essentially parallel to the inner surface of the lower wall.

The method according to the present invention for coating or treating a substrate in a reaction chamber of a reactor for atomic layer deposition (ALD), the reaction chamber being configured to generate capacitively coupled plasma, comprises the steps of exposing the substrate to alternately repeated surface reactions of two or more gas-phase reactants, wherein the reactants comprise a first reactant. The method according to the present invention further comprises the steps of inputting the first reactant into the reaction chamber through a first inlet, and inputting the two or more reactants into the reaction chamber such that the two or more reactants flow through a reaction space within the reaction chamber across the substrate in a direction essentially parallel to the inner surface of the lower wall of the reaction space.

The reaction chamber according to the present invention is used in a process for coating or treating a substrate by exposing the substrate to alternately repeated surface reactions of two or more gas-phase reactants.

Exposure of the substrate to alternately repeated surface reactions should be understood as meaning an exposure of the substrate to surface reactions of two or more reactants, one reactant at a time. This type of exposure is used e.g. in the ALD or in an ALD-like process.

By leading all the reactants in a process across the substrate and the reaction space in a cross flow geometry, i.e. across the substrate in a direction essentially parallel to the inner surface of the lower wall of the reaction space, the time of the ALD cycle may be reduced as opposed to a showerhead flow geometry. This results from the faster dynamics in the cross flow pattern where reactants flow through the reaction chamber as a travelling wave. This also enables the reactants to be spread similarly over the substrates, which facilitates process control as flow dynamics do not have to be optimized differently for different reactants. This leads to improved uniformity in the growing film. The optimization of flow dynamics and flow patterns of the reactants is especially important for processes using plasma since the high reactivity of plasma and radicals may cause nonuniformities in the growing film even with relatively small variations in concentration on the surface of the substrate.

In another embodiment of the present invention the reaction chamber comprises a second electrode located below the upper wall of the reaction chamber within the reaction chamber and a second inlet in a flow connection with a gas source and isolated from a flow connection with the sources for the reactants outside the reaction chamber. The second inlet is positioned to lead the gas into the space in between the second electrode and the lower wall through at least one hole in the second electrode in a direction essentially perpendicular to the inner surface of the lower wall. The second inlet leading gas into the reaction chamber from above the second electrode in a showerhead configuration enables homogeneous plasma to be generated from the gas independently of the reactants, which brings flexibility to processing. Furthermore, bringing plasma on the substrate in a showerhead configuration improves the uniformity of the growing film as plasma and radicals are distributed more uniformly over the substrates compared to cross flow geometry. The gas which is used to generate plasma depends on the particular process chemistry and may be e.g. nitrogen, argon or oxygen.

In one embodiment of the present invention the reaction chamber comprises an input region comprising two or more holes in a flow connection with the first inlet of the reaction chamber to input the first reactant into the reaction space. The input region extends partially around the inner circumference of the reaction chamber next to the at least one side wall of the reaction chamber, such that the holes closest to the endpoints of the circumferential input region are separated by a distance of about 30 percent of the inner circumference as measured along the inner circumference. Here the distance is measured along the inner circumference in a plane parallel to the inner surface of the lower wall of the reaction chamber, which may, in some embodiments of the invention, be the surface supporting the substrate. Here the endpoints mean the points where the adjustment means for separating the input region from the output region are located. This shape of the input region improves the uniformity of film growth when reactants flow across a substrate in cross flow geometry.

In another embodiment of the present invention the reaction chamber comprises adjustment means at the endpoints of the input region next to the at least one side wall of the reaction chamber for adjusting the length of the input region.

In another embodiment of the present invention the reaction chamber comprises an input region comprising two or more holes in a flow connection with the first inlet of the reaction chamber to input the first reactant into the reaction space. The input region extends completely around the inner circumference of the reaction chamber next to the at least one side wall of the reaction chamber. This shape of the input region may improve the uniformity of film growth and speed up the flow dynamics when the two or more reactants flow across a substrate in cross flow geometry.

In another embodiment of the present invention the reaction chamber comprises an output region in a flow connection with the outlet, located in the middle part of the lower wall of the reaction chamber.

In another embodiment of the present invention the reaction chamber comprises an output region comprising two or more holes in a flow connection with the outlet of the reaction chamber to output gases from the reaction space. The output region extends partially around the inner circumference of the reaction chamber next to the at least one side wall of the reaction chamber, such that the holes closest to the endpoints of the circumferential output region are separated by a distance of about 65 percent of the inner circumference as measured along the inner circumference. Here the distance is measured along the inner circumference in a plane parallel to the inner surface of the lower wall of the reaction chamber, which may, in some embodiments of the invention, be the surface supporting the substrate. Here the endpoints mean the points where the adjustment means for separating the input region from the output region are located. This shape of the output region may improve the uniformity of film growth when the two or more reactants flow across a substrate in cross flow geometry.

In yet another embodiment of the present invention the reaction chamber comprises adjustment means next to the at least one side wall of the reaction chamber to adjust the length of the output region.

When the reactants in the ALD process are input to the reaction chamber such that the reactants flow across the substrates as a travelling wave in the cross flow configuration the uniformity of the growing film is improved by suitably arranging the input region of the reactants around the substrates. The input region may e.g. extend partly around the substrates in which case the output region may correspondingly extend around the substrates across the reaction chamber. In the case that the input region extends completely around the inner circumference of the reaction chamber next to the at least one side wall of the reaction chamber the output region may be located in the middle part of the lower wall of the reaction chamber. In this configuration reactants may flow radially from the perimeter of the reaction chamber towards the middle part of the lower wall across the substrates which may be placed around the output region.

In another embodiment of the present invention the first inlet and the outlet are located on the lower wall of the reaction chamber.

In another embodiment of the present invention the reaction chamber comprises a first electrode below the second electrode, wherein the reaction chamber is configured to generate direct plasma in between the first electrode and the second electrode so that the substrate may be placed in between the electrodes.

In another embodiment of the present invention the reaction chamber comprises a first electrode below the second electrode, wherein the reaction chamber is configured to generate remote plasma in between the first electrode and the second electrode, so that the substrate may be placed below the first electrode, to expose the substrate essentially to radicals.

In yet another embodiment of the present invention the first electrode is perforated comprising at least one hole to uniformly distribute the gas flowing through the electrode. The holes enable the first electrode placed in between the substrate and the second electrode to act as a showerhead-type flow guide, which distributes the gas more uniformly over the substrates placed underneath the first electrode.

In another embodiment of the present invention the method according to the present invention comprises the step of inputting gas through a second inlet into the reaction chamber in the space in between a second electrode and the lower wall. The gas is input in a direction essentially perpendicular to the inner surface of the lower wall.

The embodiments of the invention described hereinbefore may be used in any combination with each other. Several of the embodiments may be combined together to form a further embodiment of the invention. A method or an apparatus, to which the invention is related, may comprise at least one of the embodiments of the invention described hereinbefore.

### DETAILED DESCRIPTION OF THE INVENTION

In the following, the present invention will be described in more detail with references to the accompanying figures, in which

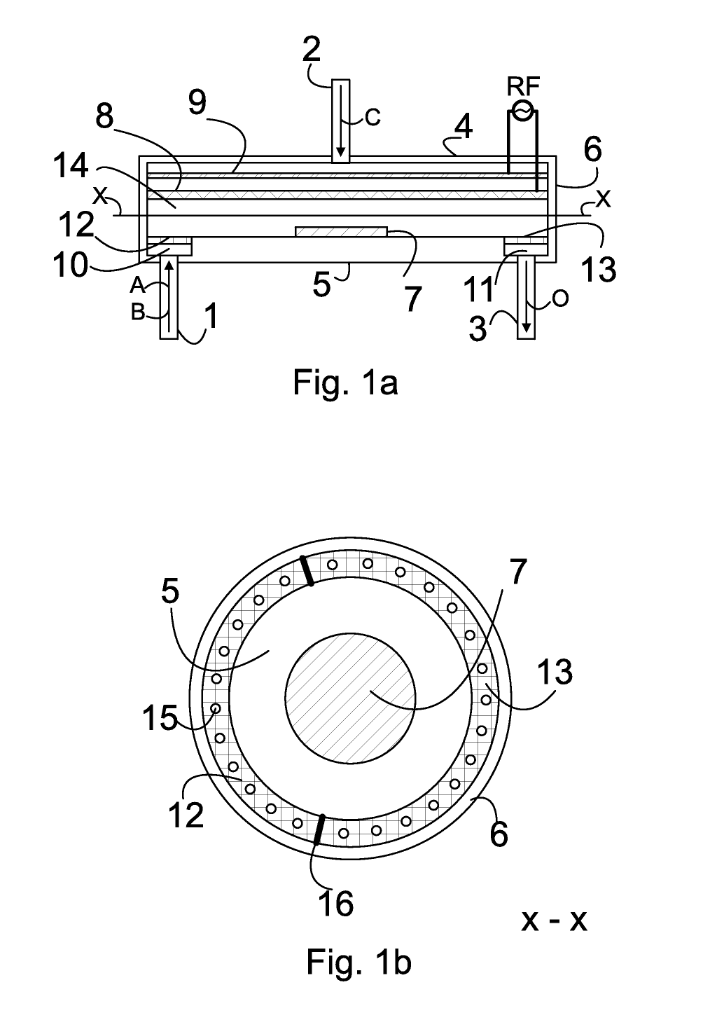

FIG. 1a is a schematic illustration of a cross section of a reaction chamber according to one embodiment of the present invention,

FIG. 1b schematically presents a cross-section of the reaction chamber illustrated in FIG. 1a,

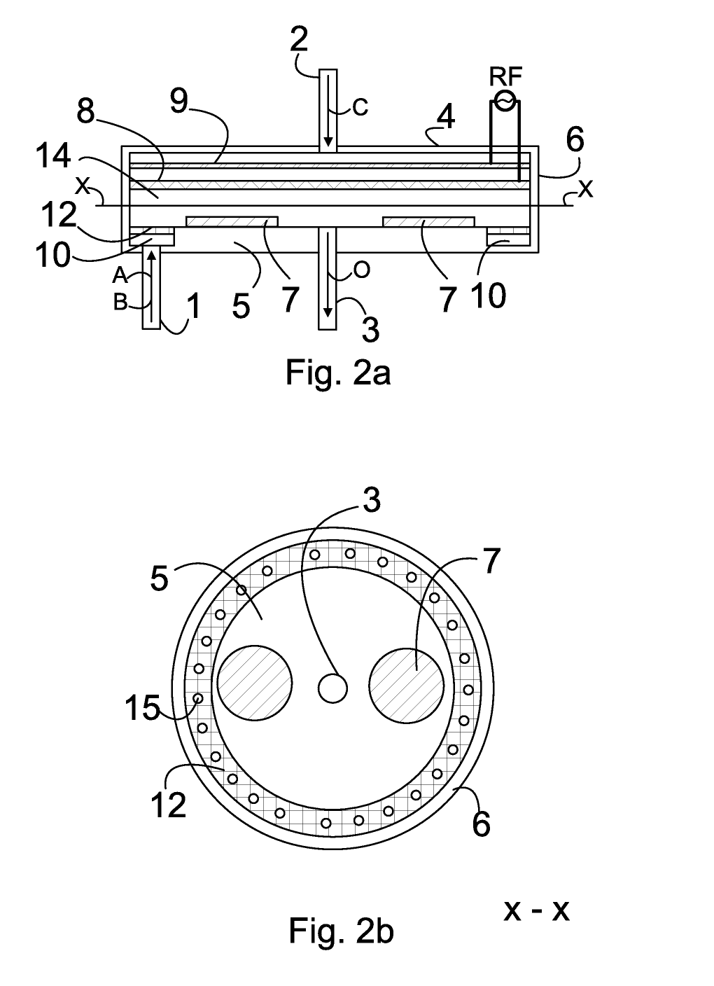

FIG. 2a is another schematic illustration of a cross section of a reaction chamber according to one embodiment of the present invention,

FIG. 2b schematically presents a cross-section of the reaction chamber illustrated in FIG. 2a.

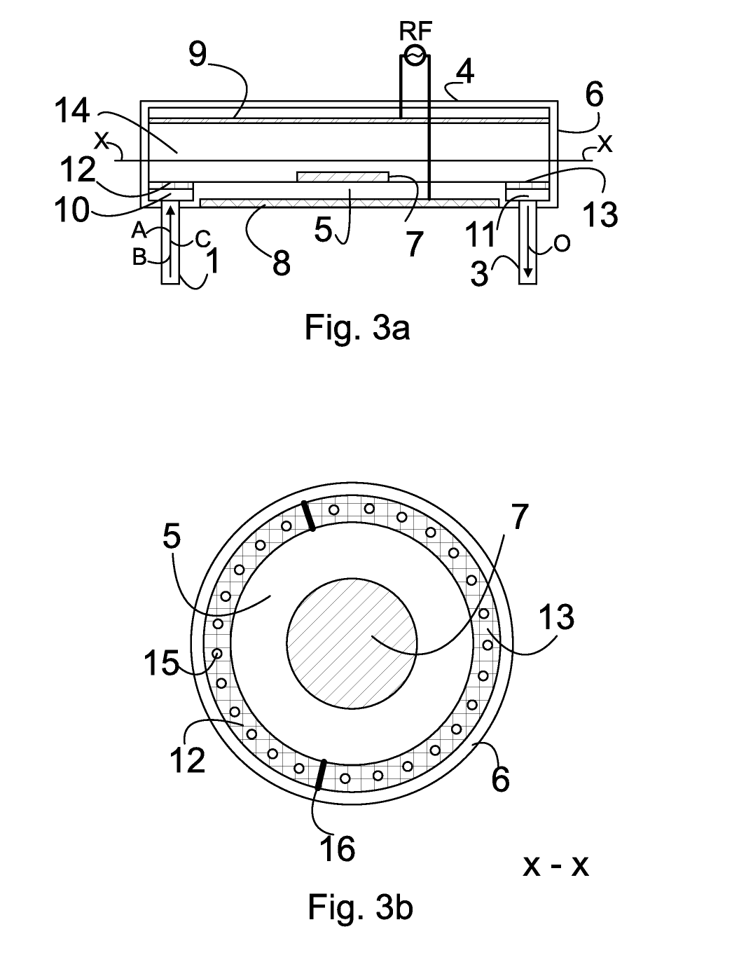

FIG. 3a is another schematic illustration of a cross section of a reaction chamber according to one embodiment of the present invention,

FIG. 3b schematically presents a cross-section of the reaction chamber illustrated in FIG. 3a and

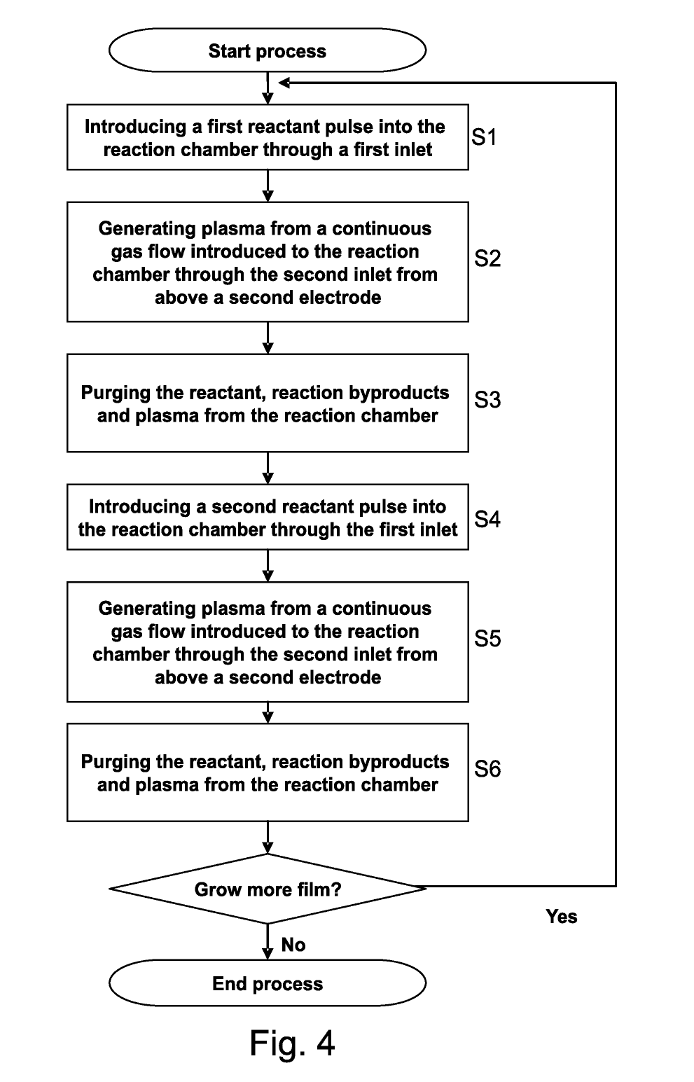

FIG. 4 is a flow-chart illustration of a method according to one embodiment of the present invention.

Unless stated otherwise, the “reaction chamber” should be understood as meaning a construction in an atomic layer deposition (ALD) reactor. The reaction chamber may comprise e.g. an input and an output, electrodes, and possible support structures.

Unless stated otherwise, the “reaction space” should be understood as meaning a space within the reaction chamber where reactions responsible for film growth essentially take place. The reaction space commonly resides in proximity to the substrate.

Unless stated otherwise, a “reactant” should be understood as meaning a precursor comprising an essential constituent of the growing deposit.

Unless stated otherwise, the “gas” should be understood as meaning any gas from which plasma may be generated but does not comprise an essential constituent of the growing deposit.

Unless stated otherwise, “gases” should be understood as meaning any kind of gaseous substance.

Unless stated otherwise, “plasma” should be understood as comprising any gaseous substance resulting from the application of RF-power, including uncharged (neutral) radicals.

The reaction chamber of FIGS. 1a and 1b comprises a first inlet 1, a second inlet 2, an outlet 3, an upper wall 4, a lower wall 5 and side walls 6. Further comprised within the reaction chamber are the reaction space 14, a first electrode 8, a second electrode 9 and a substrate 7 which may be of any shape. The input region 12 and the output region 13 extend around the inner circumference of the reaction chamber. A cross sectional view of the reaction chamber in FIG. 1a is illustrated in FIG. 1b, which indicates the location of adjustment means 16, for controlling the relative lengths of the input region 12 and the output region 13, and the location of holes 15 in the input region 12 and in the output region 13. An ALD reactor, in which the reaction chamber is located, may further comprise high-speed pulsing valves capable of introducing the reactants into the reaction space 14 as short, discrete, pulses through a pipework in the ALD reactor.

When a pulse of first reactant A is introduced to the reaction chamber the first reactant A flows through the first inlet 1 into an input space 10 under the input region 12. The input region 12 and the input space 10 under the input region 12 extend around the inner circumference of the reaction chamber along the side walls 6. The input region 12 comprises several holes 15 through which the pulse of first reactant A flows over and across the substrate 7 to the output region 13 also extending partially around the inner circumference of the reaction chamber along the side walls 6. From the output region 13 the first reactant A further flows into an output space 11 and finally out of the reaction chamber through the outlet 3. The output region 13 also comprises several holes 15 through which the first reactant A flows into the outlet 3. The second reactant B is also input to the first inlet 1 and follows essentially the same flow path as the first reactant A.

The input space 10 under the input region 12 and the output space 11 under the output region 13 are separated from each other by adjustment means 16 extending through a circular perforated plate comprising the input region 12 and the output region 13. The adjustment means 16 blocks the direct flow of reactants A, B from the input space 10 under the input region 12 to the output space 11 under the output region 13 so that the reactants A, B are forced to flow over the substrate 7.

Plasma is generated in between a first electrode 8 and a second electrode 9 by capacitive coupling. RF-power is coupled between the first electrode 8 and the second electrode 9 which causes ionization of atoms or molecules injected in between the two electrodes 8, 9. When a suitable gas flows through the gap between the electrodes 8, 9 it gets ionized and plasma and radicals are generated.

In the reaction chamber of FIGS. 1a and 1b plasma is generated as remote plasma as the substrate is placed outside the gap between the first electrode 8 and the second electrode 9. Plasma is generated from the gas C introduced to the reaction chamber through a second inlet 2 from above the second electrode 9. When a suitable gas C flows through the gap between the electrodes 8, 9 it gets ionized and plasma is generated. From between the electrodes the plasma flows to the reaction space 14 through one or more holes in the first electrode 8 and through one or more holes in the second electrode 9. In the reaction space above the substrate 7 the plasma (mainly neutral radicals in this case) participates in the chemical reactions resulting in film-growth or other treatment on the substrate 7.

In the case of remote plasma, it is common that the ionized atoms or molecules generated in between the electrodes 8, 9 are not able to significantly affect the reactions responsible for film growth near the surface of the substrate 7. The neutral radicals generated as a result of the applied RF-power may on the other hand travel close to the substrate 7 and are therefore able to participate in the reactions responsible for film growth. In this case the process is often called a radical enhanced (or assisted) process (e.g. radical enhanced ALD). This is a variation of a conventional plasma process.

Since plasma is very reactive it is important to homogeneously distribute it over the substrate 7. In the reaction chamber of FIGS. 1a and 1b plasma is introduced to the reaction space essentially perpendicularly to the inner surface of the lower wall 5 and a showerhead may be used to homogeneously distribute the plasma over the substrate 7. Especially the first electrode 8 may be used as a showerhead-type flow-guide comprising many small holes throughout its surface to distribute the plasma. Simultaneously, as the reactants A, B are introduced to the reaction space 14 below the first electrode 8 so that they flow through the reaction space 14 across the substrate 7 in a cross flow geometry, the flow dynamics for the reactants A, B is faster than in the showerhead geometry. Hence the reaction chamber of FIG. 1a and 1b combines the benefits of homogeneous plasma distribution and fast flow dynamics for the reactants A, B enabling fast ALD processing and uniform films.

Various chemical reactions occurring in the reaction space 14 produce a gas mixture which may comprise reactant A, B, carrier gas, which is used to transfer the reactant A, B into the reaction space 14 from other parts of the ALD reactor, and reaction byproducts. This gas mixture is designated by O in the outlet 3.

For reasons of simplicity, the previous item numbers will be maintained in the following exemplary embodiments in the case of repeating components.

The reaction chamber of FIGS. 2a and 2b comprises a first inlet 1, a second inlet 2, an outlet 3, an upper wall 4, a lower wall 5 and side walls 6. Further comprised within the reaction chamber are the reaction space 14, a first electrode 8, a second electrode 9 and substrates 7. The input region 12 extends completely around the inner circumference of the reaction chamber. A cross sectional view of the reaction chamber of FIG. 2a is illustrated in FIG. 2b, which indicates the location of holes 15 in the input region 12.

When a pulse of first reactant A is introduced to the reaction chamber the first reactant A flows through the first inlet 1 into an input space 10 under the input region 12. The input region 12 and the input space 10 under the input region 12 extend completely around the inner circumference of the reaction chamber along the side walls 6. The input region 12 comprises several holes 15 through which the pulse of first reactant A flows over and across the substrates 7 radially to the outlet 3 located in the middle part of the lower wall 5 of the reaction chamber. Finally the reactant flows out of the reaction chamber through the outlet 3. The second reactant B is also input to the first inlet 1 and follows essentially the same flow path as the first reactant A.

In the reaction chamber of FIGS. 2a and 2b plasma is generated as remote plasma as the substrates 7 are placed outside the gap between the first electrode 8 and the second electrode 9. Plasma is generated from gas C introduced to the reaction chamber through a second inlet 2 from above the second electrode 9. When a suitable gas C flows through the gap between the electrodes 8, 9 it gets ionized and plasma is generated. From between the electrodes the plasma flows to the reaction space 14 through one or more holes in the first electrode 8 and through one or more holes in the second electrode 9. In the reaction space 14 above the substrates 7 the plasma (mainly neutral radicals in this case) participates in the chemical reactions resulting in film-growth or other treatment on the substrates 7.

In the reaction chamber of FIGS. 2a and 2b plasma is introduced to the reaction space essentially perpendicularly to the inner surface of the lower wall 5 and a showerhead may be used to homogeneously distribute the plasma over the substrates 7. Especially the first electrode 8 may be used as a showerhead-type flow-guide comprising many small holes throughout its surface to distribute the plasma. Simultaneously, as the reactants A, B are introduced to the reaction space 14 below the first electrode 8 so that they flow through the reaction space 14 across the substrate 7 in a cross flow geometry, the flow dynamics for the reactants A, B is faster than in a showerhead geometry. Hence the reaction chamber of FIGS. 2a and 2b combines the benefits of homogeneous plasma distribution and fast flow dynamics for the reactants A, B enabling fast ALD processing and uniform films.

The reaction chamber of FIGS. 3a and 3b comprises a first inlet 1, an outlet 3, an upper wall 4, a lower wall 5 and side walls 6. Further comprised within the reaction chamber are the reaction space 14, a second electrode 9 and a substrate 7. A first electrode 8 is located below the substrate 7 so that the substrate resides in between the electrodes 8, 9. The input region 12 and the output region 13 extend partially around the inner circumference of the reaction chamber. A cross sectional view of the reaction chamber of FIG. 3a is illustrated in FIG. 3b, which indicates the location of adjustment means 16, for controlling the relative lengths of the input region 12 and the output region 13, and the location of holes 15 in the input region 12 and in the output region 13.

When a pulse of first reactant A is introduced to the reaction chamber the first reactant A flows through the first inlet 1 into an input space 10 under the input region 12. The input region 12 and the input space 10 under the input region 12 extend partially around the inner circumference of the reaction chamber along the side walls 6. The input region 12 comprises several holes 15 through which the pulse of first reactant A flows over and across the substrate 7 to the output region 13 also extending partially around the inner circumference of the reaction chamber along the side walls 6. From the output region 13 the first reactant A further flows into an output space 11 and finally out of the reaction chamber through the outlet 3. The output region 13 also comprises several holes 15 through which the first reactant A flows into the outlet 3. The second reactant B is also input to the first inlet 1 and follows essentially the same flow path as the first reactant A.

The input space 10 under the input region 12 and the output space 11 under the output region 13 are separated from each other by adjustment means 16 extending through a circular perforated plate comprising the input region 12 and the output region 13. The adjustment means 16 blocks the direct flow of the reactants A, B from the input space 10 under the input region 12 to the output space 11 under the output region 13 so that the reactants A, B are forced to flow over the substrate 7.

In the reaction chamber of FIGS. 3a and 3b plasma is generated as direct plasma as the substrate 7 is placed inside the gap between the first electrode 8 and the second electrode 9. Plasma is generated from the reactants A, B and/or gas C introduced to the reaction chamber through the first inlet 1. When the reactants A, B and/or gas C flow through the gap between the electrodes 8, 9 they get ionized and plasma is generated in the reaction space 14 above the substrate 7. The plasma participates in the chemical reactions resulting in film-growth or other treatment on the substrate 7.

In the reaction chamber of FIGS. 3a and 3b the reactants A, B and possible other gases are introduced to the reaction space 14 so that they flow through the reaction space 14 across the substrate 7 in cross flow geometry. In this way the flow dynamics in the reaction chamber is faster than in the showerhead geometry. Additionally since plasma is generated directly above the substrate a higher plasma density may be achieved than in a showerhead geometry utilizing remote plasma. Hence the reaction chamber of FIGS. 3a and 3b combines the benefits of fast flow dynamics necessary for fast ALD processing and high plasma density.

FIG. 4 presents a flow chart of a method for coating or treating a substrate by an ALD process, according to one embodiment of the present invention. In the first step S1 of the process a pulse of first reactant (e.g. reactant A) is introduced to the reaction chamber through a first inlet 1 in cross flow geometry. In the second step S2 of the process plasma may be generated from a continuous stream of gas flow introduced to the reaction space 14 from above the second electrode 9 in a showerhead configuration. In the third step S3 of the process the reaction by-products, surplus plasma and surplus reactants are purged from the reaction chamber so that the following reactant pulse of a second reactant may be introduced to the reaction chamber. In steps four S4, five S5 and six S6 of the flow chart the first three steps (S1, S2, and S3) are repeated for a second reactant (e.g. reactant B) which is introduced to the reaction chamber through the first inlet 1 also in cross flow geometry. The six steps presented in the flow chart of FIG. 4 form one ALD cycle and may ideally grow one monolayer of film. If more film is to be grown the cycle comprising the six aforementioned steps (S1-S6) may be repeated.

The timing of each step in the ALD process of FIG. 4 depends e.g. on the process chemistry and on the targeted film properties. Plasma may be continuously generated by constantly supplying RF-power between the electrodes 8, 9 or only as pulses at a certain point of the ALD cycle before, during or after a reactant A, B pulse. The pulsing of plasma may also be realized by pulsing the RF-power and/or by supplying the molecules (vapour) from which the plasma is generated in between the electrodes 8, 9 in a pulsed manner.

Furthermore plasma may be generated by supplying RF-power to the reaction chamber for one or more reactant pulses in one ALD cycle. For example, if RF-power is to be used to produce ions and/or radicals from only the first reactant in the process of FIG. 4 step S5 may be removed from the ALD cycle.

In the previous exemplary embodiments only two different reactants (A and B) are being used to discuss the operation of the reaction chamber and the method according to some embodiments of the present invention. In an ALD process more than two different reactants may naturally be used to produce film with a certain composition. In the reaction chamber and in the method, according to only some embodiments of the present invention the reactants are supplied through the same inlet and flow essentially along the same flow paths through the reaction chamber.

As is clear for a person skilled in the art, the invention is not limited to the examples described above but the embodiments can freely vary within the scope of the claims.

1. A reaction chamber of an atomic layer deposition (ALD) reactor for coating or treating a substrate by exposing the substrate to alternately repeated surface reactions of two or more gas-phase reactants, wherein the reactants comprise a first reactant, the reaction chamber being configured to generate capacitively coupled plasma and comprising
an upper wall, a lower wall with an essentially planar inner surface for supporting the substrate and at least one side wall extending between the upper wall and the lower wall, to together define a reaction space within said reaction chamber,
a first inlet to guide gases into the reaction chamber and
an outlet to lead gases out of the reaction chamber,
wherein the first inlet is in flow connection outside the reaction chamber with a source for the first reactant for leading the first reactant into the reaction chamber through the first inlet, and in that the reaction chamber is configured to lead the two or more reactants into the reaction chamber such that the two or more reactants may flow through the reaction space across the substrate in a direction essentially parallel to the inner surface of the lower wall, and the reaction chamber comprises a second electrode located below the upper wall of the reaction chamber within the reaction chamber.

2. The reaction chamber of claim 1, wherein the reaction chamber comprises a second inlet in a flow connection with a gas source and isolated from a flow connection with the sources for the reactants outside the reaction chamber, wherein the second inlet is positioned to lead the gas into the space in between the second electrode and the lower wall through at least one hole in the second electrode in a direction essentially perpendicular to the inner surface of the lower wall.

3. The reaction chamber of claim 1, wherein the reaction chamber comprises an input region comprising two or more holes in a flow connection with the first inlet of the reaction chamber to input the first reactant into the reaction space, said input region extending partially around the inner circumference of the reaction chamber next to the at least one side wall of the reaction chamber, such that the holes closest to the endpoints of the circumferential input region are separated by a distance of about 30 percent of the inner circumference as measured along the inner circumference.

4. The reaction chamber of claim 3, wherein the reaction chamber comprises adjustment means at the endpoints of the input region next to the at least one side wall of the reaction chamber for adjusting the length of the input region.

5. The reaction chamber of claim 1, wherein the reaction chamber comprises an input region comprising two or more holes in a flow connection with the first inlet of the reaction chamber to input the first reactant into the reaction space, said input region extending completely around the inner circumference of the reaction chamber next to the at least one side wall of the reaction chamber.

6. The reaction chamber of claim 5, wherein the reaction chamber comprises an output region in a flow connection with the outlet, located in the middle part of the lower wall of the reaction chamber.

7. The reaction chamber of claim 1, wherein the reaction chamber comprises an output region comprising two or more holes in a flow connection with the outlet of the reaction chamber to output gases from the reaction space, said output region extending partially around the inner circumference of the reaction chamber next to the at least one side wall of the reaction chamber, such that the holes closest to the endpoints of the circumferential output region are separated by a distance of about 65 percent of the inner circumference as measured along the inner circumference.

8. The reaction chamber of claim 7, wherein the reaction chamber comprises adjustment means next to the at least one side wall of the reaction chamber to adjust the length of the output region.

9. The reaction chamber of claim 1, wherein the first inlet and the outlet are located on the lower wall of the reaction chamber.

10. The reaction chamber of claim 1, the reaction chamber comprises a first electrode below the second electrode, wherein the reaction chamber is configured to generate direct plasma in between the first electrode and the second electrode so that the substrate may be placed in between the electrodes.

11. The reaction chamber of claim 1 wherein the reaction chamber comprises a first electrode below the second electrode, wherein the reaction chamber is configured to generate remote plasma in between the first electrode and the second electrode, so that the substrate may be placed below the first electrode, to expose the substrate essentially to radicals.

12. The reaction chamber of claim 11, wherein the first electrode is perforated comprising at least one hole to uniformly distribute the gas flowing through the electrode.

13. A method for coating or treating a substrate in a reaction chamber of a reactor for atomic layer deposition (ALD), the reaction chamber being configured to generate capacitively coupled plasma, said method comprising the steps of exposing the substrate to alternately repeated surface reactions of two or more gas-phase reactants, wherein the reactants comprise a first reactant, wherein the method comprises the steps of
inputting the first reactant into the reaction chamber through a first inlet, and
inputting the two or more reactants into the reaction chamber such that the two or more reactants flow through a reaction space within the reaction chamber across the substrate in a direction essentially parallel to the inner surface of the lower wall of the reaction space, and
inputting gas into the reaction chamber in the space between a second electrode, located below the upper wall of the reaction chamber within the reaction chamber, and the lower wall.

14. The method of claim 13, wherein inputting gas into the reaction chamber comprises inputting gas through a second inlet into the reaction chamber in the space in between the second electrode and the lower wall, the gas being input in a direction essentially perpendicular to the inner surface of the lower wall.

15. Use of the reaction chamber of claim 1 in a process for coating or treating a substrate by exposing the substrate to alternately repeated surface reactions of two or more gas-phase reactants.
